(19) United States
(12) Patent Application Publication
(10) Pub. No.: US 2026/0040640 A1
(43) Pub. Date: Feb. 5, 2026

(54) SEMICONDUCTOR DEVICE, POWER CONVERSION APPARATUS, AND METHOD OF MANUFACTURING SEMICONDUCTOR DEVICE

(71) Applicant: Mitsubishi Electric Corporation, Tokyo (JP)

(72) Inventors: Yutaka FUKUI, Tokyo (JP); Takaaki TOMINAGA, Tokyo (JP); Yusuke YAMASHIRO, Tokyo (JP)

(73) Assignee: Mitsubishi Electric Corporation, Tokyo (JP)

(21) Appl. No.: 18/995,890

(22) PCT Filed: Jul. 29, 2022
(86) PCT No.: PCT/JP2022/029248

§ 371 Date: Jan. 17, 2025

(51) Int. Cl. H10D 62/60; H02M 7/5387; H10D 30/01; H10D 30/66; H10D 62/10

(52) U.S. Cl. CPC H10D 62/60; H02M 7/5387; H10D 30/0297; H10D 30/668; H10D 62/102; H10D 62/124

(57) ABSTRACT

A semiconductor device includes: first pillar regions of a second conductivity type each formed on a lower side of the plurality of gate trenches into which a gate electrode is embedded; and a second pillar region of a first conductivity type formed between the first pillar regions adjacent to each other and having a higher impurity peak concentration than the drift layer. The second pillar region is made of a high concentration region and a low concentration region provided to at one lateral part of the second pillar region and having a lower impurity peak concentration than the high concentration region.

### TECHNICAL FIELD

The present disclosure relates to a semiconductor device, and particularly to a trench gate type semiconductor device.

### BACKGROUND ART

In a power electronic apparatus, execution and suspension of electrical power supply needs to be switched to drive a load such as an electrical motor. Used accordingly is a switching element such as an insulated gate bipolar transistor (IGBT) or a metal oxide semiconductor field effect transistor (MOSFET) using silicon.

A MOSFET and an IGBT having a vertical structure are often adopted to a switching device assumed to be used as a power semiconductor device, and are referred to as “vertical MOSFET” and “vertical IGBT”, respectively. The vertical MOSFET and the vertical IGBT have a planar gate type and a trench gate type in accordance with a gate structure.

In the trench gate type MOSFET (referred to as “gate trench” hereinafter) in which a gate electrode is embedded into an active region of a first conductivity type (an n type, for example) drift layer, high electrical field is applied to a gate insulating film in a bottom surface of the gate trench in an OFF state due to a structure thereof, and the gate insulating film may be broken in the bottom surface of the gate trench.

For example, Patent Document 1 discloses, as a technique for solving this problem, a technique of providing “a trench bottom part protection layer” as a second conductivity type (a p type, for example) electrical field reduction region to cover the bottom surface of the gate trench, thereby reducing electrical field on the gate insulating film in the bottom surface of the gate trench. Furthermore, in Patent Document 1, “a depletion suppressing layer” as a first conductivity type current diffusion layer is provided to a side surface of the gate trench to prevent narrowing of a route of ON current between a gate and a trench by the trench bottom part protection layer and reduce conduction loss in an ON state. The depletion suppressing layer in Patent Document 1 is formed by implanting a first conductivity type impurity as a donor into a side surface of the gate trench by an inclined ion implantation.

### PRIOR ART DOCUMENTS

### Patent Document(s)

Patent Document 1: U.S. Pat. No. 6,377,309 in Patent Gazette.

### SUMMARY

### Problem to be Solved by The Invention

When the trench bottom part protection layer and the depletion suppressing layer described above extend deeply into the drift layer and are used as a p-type pillar region and an n-type pillar region having a semi-super junction structure, reduction of resistance and high breakdown voltage can be achieved in the trench gate type MOSFET. The semi-super junction structure indicates a super junction structure in which a p-type pillar region and an n-type pillar region are formed to a depth in a midway part of a semiconductor layer.

However, in a case where the n-type pillar region as the depletion suppressing layer is formed in a shallow position of the gate trench by the inclined ion implantation, when there is a variation in a width or a depth of the gate trench, a large amount of donor (an n-type dopant) is implanted into the p-type pillar region as the trench bottom part protection layer. Then, charge balance is hardly performed on the p-type pillar region and the n-type pillar region, and variation occurs in withstand voltage characteristics of the semiconductor device; thus, an effect of reduction of resistance and high breakdown voltage is not sufficiently obtained by the semi-super junction structure.

The present disclosure is to solve the above problems, and an object of the present disclosure is to suppress implantation of a dopant of a second pillar region into a first pillar region below a gate trench in a semiconductor device having a semi-super junction structure.

### Means to Solve the Problem

A semiconductor device according to the present disclosure includes: a semiconductor layer; a drift layer of a first conductivity type formed on the semiconductor layer; a well region of a second conductivity type formed on a surface layer part of the semiconductor layer; a source region of a first conductivity type formed on a surface layer part of the well region; a source electrode electrically connected to the well region and the source region; a plurality of gate trenches passing through the source region and the well region and having an embedded gate electrode via a gate insulating film; first pillar regions of a second conductivity type each formed on a lower side of the plurality of gate trenches; and a second pillar region of a first conductivity type formed between the first pillar regions adjacent to each other and having a higher impurity peak concentration than the drift layer; wherein the second pillar region is made up of a high concentration region and a low concentration region provided to at least one lateral part of the second pillar region and having a lower impurity peak concentration than the high concentration region.

### Effects of the Invention

According to the semiconductor device of the present disclosure, implantation of a dopant of the second pillar region into the first pillar region below the gate trench can be suppressed. Accordingly, such a configuration can prevent loss of charge balance between the first pillar region and the second pillar region, and can contribute to achievement of reduction of resistance and high breakdown voltage by the semi-super junction structure.

These and other objects, features, aspects and advantages of the present disclosure will become more apparent from the following detailed description when taken in conjunction with the accompanying drawings.

### BRIEF DESCRIPTION OF DRAWINGS

FIG. 1 A cross-sectional view schematically illustrating a structure of a semiconductor device according to an embodiment 1.

FIG. 2 A cross-sectional view schematically illustrating a structure of a semiconductor device according to a modification example of the embodiment 1.

FIG. 3 A cross-sectional view schematically illustrating a structure of a semiconductor device according to a modification example of the embodiment 1.

FIG. 4 A cross-sectional view schematically illustrating a structure of a semiconductor device according to a modification example of the embodiment 1.

FIG. 5 A cross-sectional view schematically illustrating a structure of a semiconductor device according to a modification example of the embodiment 1.

FIG. 6 A cross-sectional view schematically illustrating a method of manufacturing a semiconductor device according to the embodiment 1.

FIG. 7 A cross-sectional view schematically illustrating a method of manufacturing the semiconductor device according to the embodiment 1.

FIG. 8 A cross-sectional view schematically illustrating a method of manufacturing the semiconductor device according to the embodiment 1.

FIG. 9 A plan view schematically illustrating a structure of a semiconductor device according to an embodiment 2.

FIG. 10 A cross-sectional view along an A1-A2 line in FIG. 9.

FIG. 11 A cross-sectional view along a B1-B2 line in FIG. 9.

FIG. 12 A cross-sectional view along a C1-C2 line in FIG. 9.

FIG. 13 A cross-sectional view schematically illustrating a structure of a semiconductor device according to an embodiment 3.

FIG. 14 A plan view schematically illustrating a structure of a semiconductor device according to an embodiment 4.

FIG. 15 A cross-sectional view along an A1-A2 line in FIG. 14.

FIG. 16 A cross-sectional view along a B1-B2 line in FIG. 14.

FIG. 17A cross-sectional view along a C1-C2 line in FIG. 14.

FIG. 18 A block diagram illustrating a configuration of a power conversion system according to an embodiment 5.

### DESCRIPTION OF EMBODIMENT(S)

An embodiment of a technique according to the present disclosure is described hereinafter with reference to the drawings. The drawings are schematically illustrated; thus, a mutual relationship of sizes and positions of constituent elements each illustrated in different drawing are not necessarily illustrated accurately, but can be appropriately changed. The same signs are assigned to the same or corresponding constituent elements also in the different drawings, and a repetitive description thereof is omitted in some cases. Terms indicating a position or a direction such as “upper”, “lower”, “side”, “bottom”, “front” or “rear” in the description are used for convenience of easy understanding, thus do not necessarily express a position and a direction in practical implementation.

In the embodiments hereinafter, a first conductivity type is an n type and a second conductivity type is a p type, however, it is also applicable that the first conductivity type is the p type and the second conductivity type is the n type.

### Embodiment 1

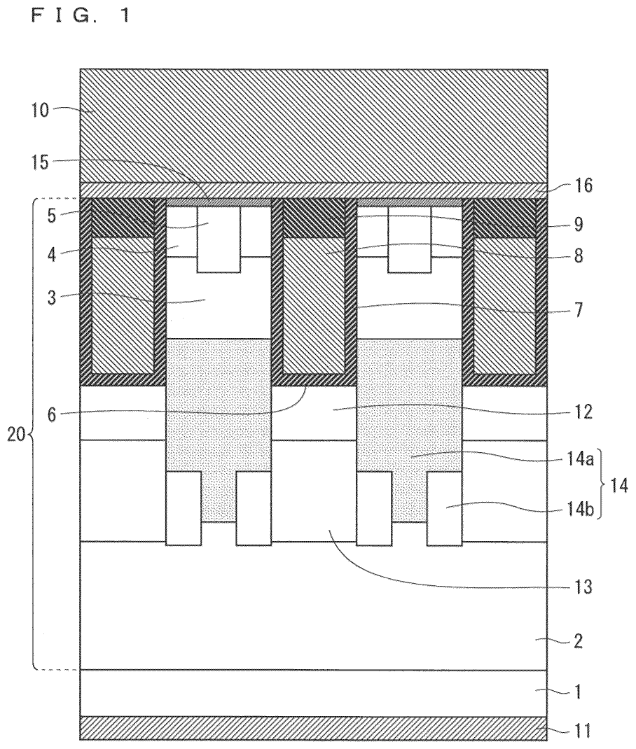

FIG. 1 is a cross-sectional view schematically illustrating a structure of a semiconductor device according to an embodiment 1. Described in the embodiment 1 is a vertical trench gate type silicon carbide MOSFET as an example of a semiconductor device. The semiconductor device according to the embodiment 1 includes an active region in which MOSFET cells (active unit cells) are formed side by side and a terminal region on an outer side of the active region, and FIG. 1 illustrates a configuration of the active region.

The semiconductor device according to the embodiment 1 is formed using an n-type (first conductivity type) semiconductor substrate 1 made of silicon carbide having a 4H polytype. A semiconductor layer 20 made of silicon carbide is formed on the semiconductor substrate 1. An upper surface of the semiconductor substrate 1 is a (0001) plane having an OFF angle θ inclined in a [11-20] axis direction. It is sufficient that the OFF angle θ is equal to or smaller than 10°. An n-type drift layer 2 having a lower impurity peak concentration than the semiconductor substrate 1 is formed on the semiconductor layer 20.

A p-type (second conductivity type) well region 3 is formed on a surface layer part of the semiconductor layer 20 in the active region. Each of an n-type source region 4 and a p-type well contact region 5 having a higher impurity peak concentration than the well region 3 is selectively (that is to say, partially) formed on a surface layer part of the well region 3. The well contact region 5 is provided to have contact with the source region 4 to electrically connect a source electrode 10 described hereinafter and the well region 3.

A gate trench 6 is formed in the semiconductor layer 20 to pass through the source region 4 and the well region 3. A gate insulating film 7 is formed on a side surface and a bottom surface of the gate trench 6. A gate electrode 8 is formed on the gate insulating film 7 to be embedded into the gate trench 6. An upper surface of the gate electrode 8 is located in a position deeper than a surface of the semiconductor layer 20. That is to say, the upper surface of the gate electrode 8 is located in a position deeper than an upper end of the gate trench 6. An interlayer insulating film 9 is formed on an upper part of the gate trench 6 to cover the gate electrode 8.

In the present embodiment, the gate trench 6 passes through the source region 4; thus, a part of an edge of the gate trench 6 in the semiconductor layer 20 is the source region 4. However, the gate electrode 8 is not formed in an upper end portion of the gate trench 6, and the gate insulating film 7 in that part is covered by the interlayer insulating film 9. Thus, the source region 4 and the gate electrode 8 do not face each other in the part of the edge of the gate trench 6.

The source electrode 10 is formed on the semiconductor layer 20. The source electrode 10 is electrically connected to the source region 4 and the well region 3. In the present embodiment, a silicide layer 15 is formed a surface of each of the source region 4 and the well contact region 5, and a barrier metal 16 is provided to a bottom surface of the source electrode 10. Thus, the source electrode 10 is connected to the source region 4 and the well contact region 5 via the silicide layer 15 and the barrier metal 16. Furthermore, a drain electrode 11 electrically connected to the semiconductor substrate 1 is formed on a lower surface of the semiconductor substrate 1.

A p-type trench bottom part protection layer 12 is formed on the bottom part of the gate trench 6 in the semiconductor layer 20. The trench bottom part protection layer 12 is electrically connected to the source electrode 10. The trench bottom part protection layer 12 has a function of reducing electrical field applied to the bottom surface and the side surface of the gate trench 6 in an OFF state of the MOSFET. The trench bottom part protection layer 12 preferably has contact with the gate trench 6.

The semiconductor layer 20 has a semi-super junction structure in which a p-type pillar region 13 as a p-type first pillar region and an n-type pillar region 14 as an n-type second pillar region are alternately disposed. The p-type pillar region 13 is formed on a lower side of the trench bottom part protection layer 12, and the n-type pillar region 14 is formed between the p-type pillar regions 13 adjacent to each other.

In the present embodiment, the n-type pillar region 14 is made up of a high concentration n-type pillar region 14a as a high concentration region and a low concentration n-type pillar region 14b as a low concentration region (the high concentration n-type pillar region 14a in each of the drawings is hatched with a sand-like pattern for convenience of the illustration). An impurity peak concentration of the high concentration n-type pillar region 14a is higher than that of the low concentration n-type pillar region 14b. The low concentration n-type pillar region 14b is disposed in at least a part of a lateral part of the n-type pillar region 14 (that is to say, a part having contact with the p-type pillar region 13). The lateral part of the n-type pillar region 14 is referred to as “the lateral part of the high concentration n-type pillar region 14a” in some cases hereinafter.

The n-type pillar region 14 is sandwiched between two p-type pillar regions 13; thus, the n-type pillar region 14 includes two lateral parts. The low concentration n-type pillar region 14b is formed in at least one of two lateral parts of the n-type pillar region 14. That is to say, the high concentration n-type pillar region 14a may be provided to only one of the lateral parts of the high concentration n-type pillar region 14a.

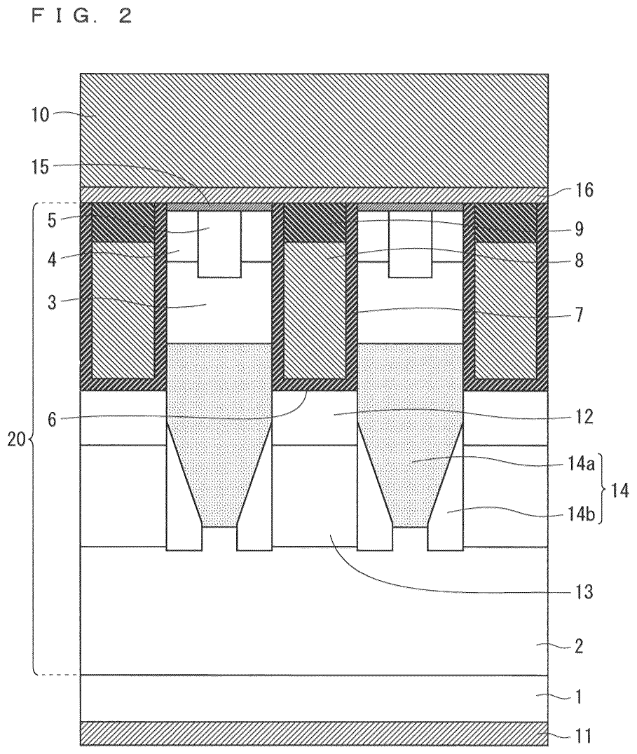

In FIG. 1, a width of an upper part of the low concentration n-type pillar region 14b is the same as that of a bottom part thereof; however, the upper surface or a lateral surface of the low concentration n-type pillar region 14b may be inclined so that the width of the bottom part of the low concentration n-type pillar region 14b is larger than that of the upper part thereof as illustrated in FIG. 2, for example.

Although details are described hereinafter, a structure of the high concentration n-type pillar region 14a and the low concentration n-type pillar region 14b illustrated in FIG. 1 and FIG. 2 is formed by performing inclined ion implantation on the lateral surfaces on both sides of the gate trench 6, that is to say, ion implantation from a direction inclined with respect to a depth direction of the semiconductor layer 20.

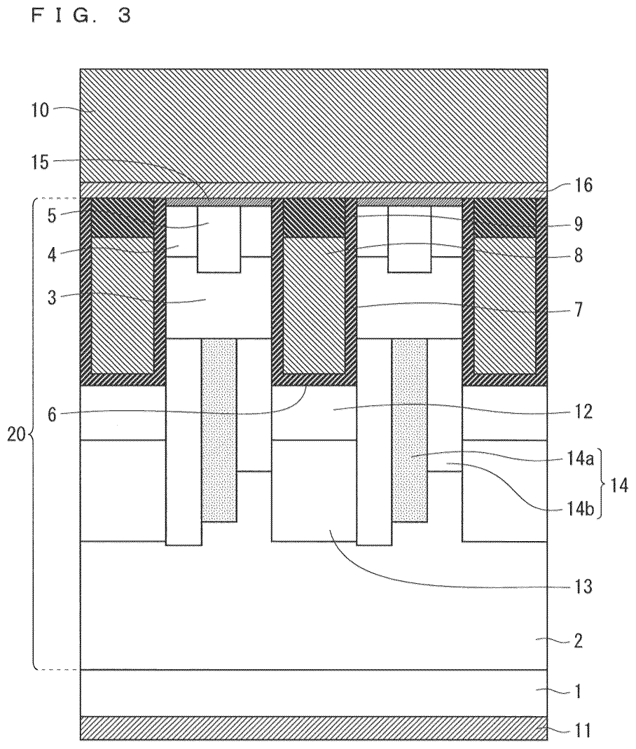

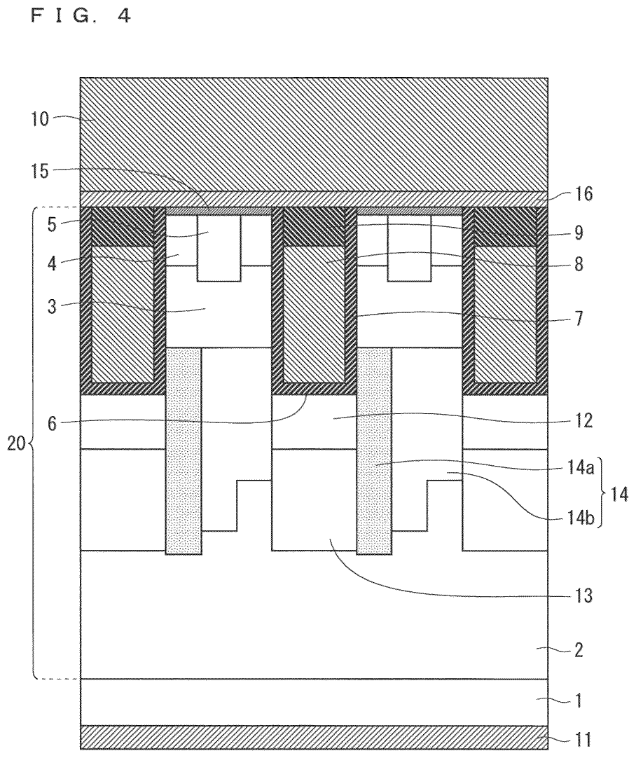

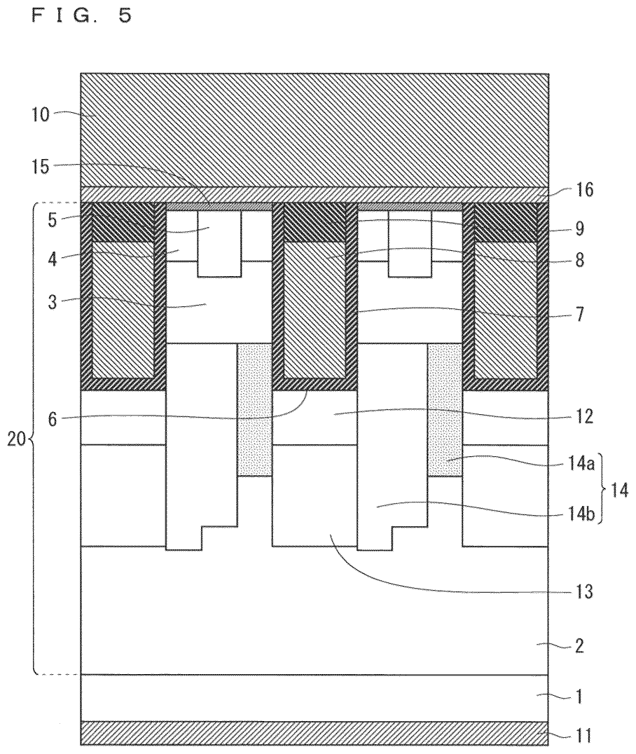

However, the n-type pillar region 14 made up of the high concentration n-type pillar region 14a and the low concentration n-type pillar region 14b can be formed only by the inclined ion implantation on the lateral surface on one side of the gate trench 6. In this case, as illustrated in FIG. 3, FIG. 4, or FIG. 5, a bottom of the n-type pillar region 14 is inclined, and a depth of the n-type pillar region 14 is bilaterally asymmetric. FIG. 3 illustrates an example of implanting a high concentration impurity into a position in an intermediate part between the lateral surface of the gate trench 6 as an implantation surface and the gate trench 6 adjacent thereto from the lateral surface of the gate trench 6 to form the low concentration n-type pillar region 14b in the inclined ion implantation. FIG. 4 is an example of implanting a high concentration impurity into a deep position (the trench bottom part protection layer 12 below the adjacent gate trench 6 and near the p-type pillar region 13) from the lateral surface of the gate trench 6 as an implantation surface for inclined ion implantation to form the low concentration n-type pillar region 14b. FIG. 5 is an example of implanting a high concentration impurity into a shallow position (the trench bottom part protection layer 12 below the adjacent gate trench 6 and near the p-type pillar region 13) from the lateral surface of the gate trench 6 as an implantation surface of inclined ion implantation to form the low concentration n-type pillar region 14b.

With regard to a positional relationship between the p-type pillar region 13 and the n-type pillar region 14 in a depth direction from an upper surface of the semiconductor layer 20, a lower end of the high concentration n-type pillar region 14a or the lower concentration n-type pillar region 14b is preferably located in a position in the same depth as or a deeper depth than a lower end of the p-type pillar region 13 to prevent narrowing current between the p-type pillar regions 13 adjacent to each other.

The p-type pillar region 13 and the n-type pillar region 14 are preferably formed to reach a position deeper than a distance between the gate trenches 6 adjacent to each other or a distance between the p-type pillar regions 13 adjacent to each other based on a position of the bottom of the gate trench 6. That is to say, a depth from the bottom of the gate trench 6 to the lower end of the p-type pillar region 13 and a depth from the bottom of the gate trench 6 to the lower end of the n-type pillar region 14 are preferably larger than the distance between the gate trenches 6 adjacent to each other or a distance between the p-type pillar regions 13 adjacent to each other.

A method of manufacturing the semiconductor device according to the embodiment 1 illustrated in FIG. 1 is described hereinafter.

Firstly, the semiconductor layer 20 made of n-type (n⁻ type) silicon carbide having relatively high resistance is epitaxially grown on a surface of the n-type semiconductor substrate 1 having a 4H polytype. At this time, it is sufficient that the semiconductor layer 20 is formed to have an n-type impurity concentration equal to or larger than 1×10¹⁴ [cm⁻³] and equal to or smaller than 1×10¹⁷ [cm⁻³].

Next, an alignment mark is formed in the semiconductor layer 20 by reactive ion etching (RIE). This alignment mark may be formed with the gate trench 6 at the same time.

Subsequently, the p-type well region 3 and the n-type (n⁺ type) source region 4 having relatively low resistance are formed by ion implantation in a surface layer part of the semiconductor layer 20 based on the alignment mark. A resist mask, for example, can be used as the ion implantation for selectively forming the source region 4 by the ion implantation.

It is sufficient that the source region 4 has an n-type impurity concentration equal to or larger than 5×10¹⁸ [cm⁻³] and equal to or smaller than 5×10²⁰[cm⁻³] and the well region 3 has a p-type impurity concentration equal to or larger than 5×10¹⁶[cm⁻³] and equal to or smaller than 5×10¹⁹[cm⁻³]. The n-type impurity concentration of the source region 4 is set to be higher than the p-type impurity concentration of the well region 3 to form the source region 4 on the surface layer part of the well region 3. At this time, an n-type region where the well region 3 and the source region 4 are not formed in the semiconductor layer 20 remains as the drift layer 2.

The impurity concentration of the well region 3 may be or may not be constant in the depth direction. For example, applicable is a distribution in which the concentration is low in a surface part of the well region 3 or a distribution in which there is a peak in a deep part.

Next, the p-type well contact region 5 is formed by the ion implantation. At this time, it is sufficient that the well contact region 5 is formed to have a p-type impurity concentration equal to or larger than 1×10¹⁹[cm⁻³] and equal to or smaller than 1×10²²[cm⁻³].

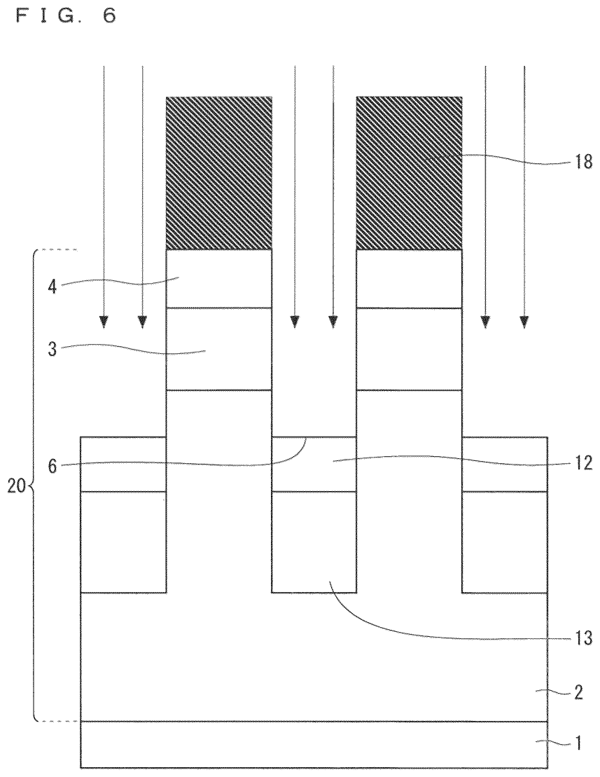

Next, an etching mask 18 (refer to FIG. 6) having a pattern in which a region where the gate trench 6 is formed is opened is formed on the semiconductor layer 20, and formed on the semiconductor layer 20 by the RIE using the etching mask 18 is the gate trench 6 passing through the well region 3 to reach the drift layer 2.

Next, as illustrated in FIG. 6, the p-type trench bottom part protection layer 12 and the p-type pillar region 13 are formed on the bottom surface of the gate trench 6 by ion implantation using the etching mask 18 as the implantation mask. At this time, it is sufficient that the trench bottom part protection layer 12 is formed to have a p-type impurity concentration equal to or larger than 1×10¹⁷[cm⁻³] and equal to or smaller than 1×10²⁰[cm⁻³], and the p-type pillar region 13 is formed to have a p-type impurity concentration equal to or larger than 1×10¹⁶[cm⁻³] and equal to or smaller than 1×10¹⁸[cm⁻³].

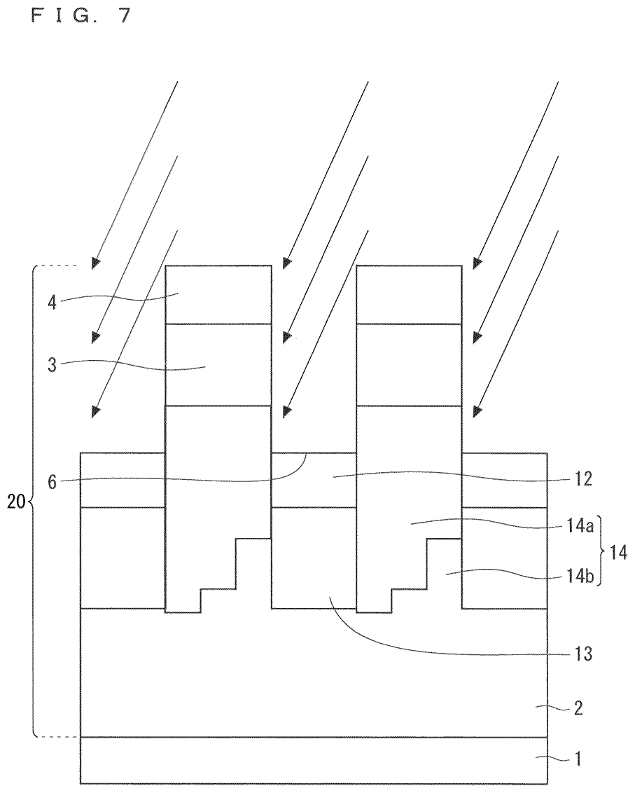

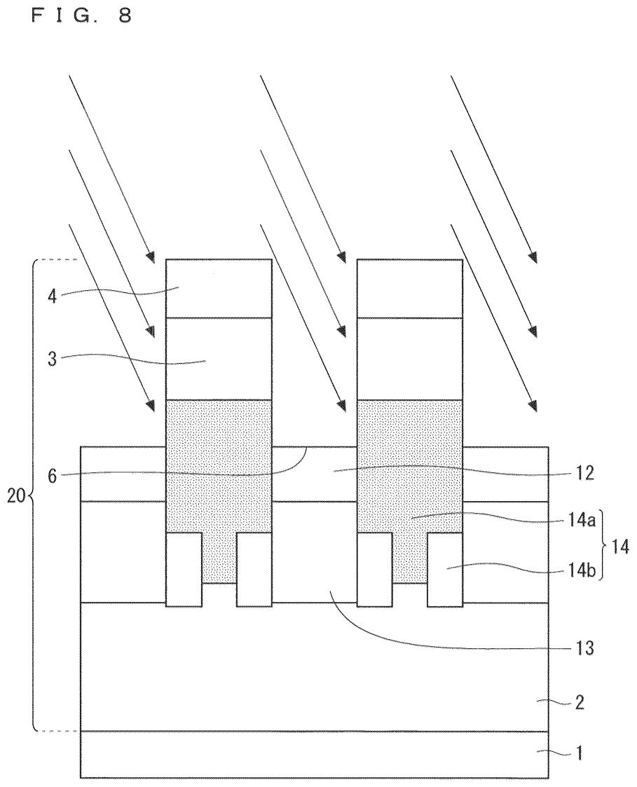

After the etching mask 18 is removed, the n-type pillar region 14 made of the high concentration n-type pillar region 14a and the low concentration n-type pillar region 14b is formed below the mesa-like semiconductor layer 20 between the gate trenches 6 by the inclined ion implantation. Specifically, as illustrated in FIG. 7, the n-type impurity is firstly implanted into one side surface of the gate trench 6 by the inclined ion implantation to form the lower concentration n-type pillar region 14b below the mesa-like semiconductor layer 20. Furthermore, as illustrated in FIG. 8, the n-type impurity is implanted also into the other side surface of the gate trench 6 by the inclined ion implantation to form the lower concentration n-type pillar region 14b below the mesa-like semiconductor layer 20. The high concentration n-type pillar region 14a is formed in a region in which the impurity is repetitively implanted by this inclined ion implantation twice.

It is important to implant the n-type impurity from the lateral surface of the gate trench 6 into the trench bottom part protection layer 12 below the gate trench 6 adjacent thereto and an area near the p-type pillar region 13 in the inclined ion implantation for forming the high concentration n-type pillar region 14a and the low concentration n-type pillar region 14b.

The lower surface of the gate trench 6 is located behind the mesa-like semiconductor layer 20 in the inclined ion implantation, and suppressed accordingly is implantation of the n-type impurity into the lower surface of the gate trench 6. Suppressed is implantation of a donor into the trench bottom part protection layer 12 and the p-type pillar region 13 below the gate trench 6, and stable charge balance can be achieved. As a structural feature, the concentration of the n-type impurity included in the p-type pillar region 13 is lower than that included in the low concentration n-type pillar region 14b.

It is sufficient that the high concentration n-type pillar region 14a has an n-type impurity concentration equal to or larger than 1×10¹⁵ [cm³] and equal to or smaller than 1×10¹⁸[cm⁻³], and the low concentration n-type pillar region 14b has an n-type impurity concentration equal to or larger than 1×10¹⁴[cm⁻³] and equal to or smaller than 1×10¹⁸[cm⁻³].

Performed subsequently is annealing for activating implanted ions for 0.5 to 60 minutes in a temperature range from 1500° C. to 2200° C.

Furthermore, an insulating film is formed on the surface of the semiconductor layer 20 by a thermal oxidation method or a chemical vapor deposition (CVD)method, and patterning is performed on the insulating film by wet etching or dry etching to form a field insulating film (not shown) for protecting a terminal region.

Next, the gate insulating film 7 is formed on the surface of the semiconductor layer 20 including an inner part of the gate trench 6 by the thermal oxidation method or the CVD method, for example.

Next, polysilicon, for example, doped with an impurity as a material of the gate electrode 8 is formed by the CVD method, for example, on a whole surface of the semiconductor layer 20 on which the gate insulating film 7 is formed. At this time, the inner part of the gate trench 6 is filled with polysilicon. When polysilicon is formed by the CVD method, polysilicon is grown not only in an upper direction but also a lateral direction from the bottom surface of the gate trench 6 in the gate trench 6; thus, the gate trench 6 can be filled with polysilicon relatively easily.

Next, polysilicon on the surface of the semiconductor layer 20 is removed by etch back. At this time, polysilicon embedded into the gate trench 6 is not removed but remains to be the gate electrode 8. When polysilicon on the surface of the semiconductor layer 20 is completely removed, over-etch is necessary in no small measure; thus, the upper surface of the gate electrode 8 in the gate trench 6 is located in a position deeper than an upper end portion of the gate trench 6.

Next, the interlayer insulating film 9 is formed to cover the terminal region and the gate electrode 8, and the source region 4 and the well contact region 5 are exposed from the interlayer insulating film 9 by dry etching, for example. Then, the silicide layer 15 is formed on an upper part of each of the well contact region 5 and the n-type source region 4. Furthermore, a gate contact hole (not shown) reaching the gate electrode 8 is formed in the interlayer insulating film 9 by dry etching or wet etching, for example.

Subsequently, the source electrode 10 is formed on the semiconductor layer 20. A gate pad connected to the gate insulating film 7 through the gate contact hole or a wiring for connection to the gate pad is formed.

Finally, the drain electrode 11 is formed on the lower surface of the semiconductor substrate 1; thus, the semiconductor device having the structure illustrated in FIG. 1 is completed.

An effect caused by the semiconductor device according to the embodiment 1 is described hereinafter.

An effect of the trench bottom part protection layer 12 is described firstly. When the trench bottom part protection layer 12 is provided to the lower side of the gate trench 6, electrical field applied to the gate insulating film 7 in an OFF state of the MOSFET can be significantly reduced.

Described next is and effect of the p-type pillar region 13 and the n-type pillar region 14 (the high concentration n-type pillar region 14a and the low concentration n-type pillar region 14b). The p-type pillar region 13 and the n-type pillar region 14 are provided to reach a deep position of the drift layer 2, and the impurity concentration of the p-type pillar region 13 and the n-type pillar region 14 is set to be larger than that of the drift layer 2 while charge balance therebetween is performed; thus, a super junction effect is obtained. That is to say, in the OFF state of the semiconductor device, a depletion layer extends in a lateral direction between the p-type pillar region 13 and the n-type pillar region 14, and larger electrical field larger than that in the drift layer 2 can be distributed to the regions of the p-type pillar region 13 and the n-type pillar region 14; thus, such a configuration can contribute to achievement of high withstand voltage of the semiconductor device. In the ON state of the semiconductor device, the n-type pillar region 14 having lower resistance than the drift layer 2 serves as a current route, thus, such a configuration can contribute to reduction of ON resistance.

Described herein is an effect of the configuration of the n-type pillar region 14 made up of the high concentration n-type pillar region 14a and the low concentration n-type pillar region 14b. In the super junction effect described above, the high concentration n-type pillar region 14a functions as a current route having lower resistance in the ON state, and the low concentration n-type pillar region 14b extends the depletion layer more easily and functions as a region having high withstand voltage in the OFF state.

Described is an effect caused by a method of forming the high concentration n-type pillar region 14a and the low concentration n-type pillar region 14b. When the high concentration n-type pillar region 14a and the low concentration n-type pillar region 14b are formed by the inclined ion implantation, the lower surface of the gate trench 6 is located behind the mesa-like semiconductor layer 20, and suppressed accordingly is implantation of the n-type impurity into the lower surface of the gate trench 6. Suppressed is implantation of a donor into the trench bottom part protection layer 12 and the p-type pillar region 13 below the gate trench 6, and stable charge balance can be achieved.

The p-type pillar region 13 and the n-type pillar region 14 are preferably formed to reach a position deeper than a distance between the gate trenches 6 adjacent to each other or a distance between the p-type pillar regions 13 adjacent to each other based on a position of the bottom of the gate trench 6 to obtain a higher super junction effect.

The cell structure formed in the active region in the semiconductor device may be an optional structure, thus may have a continuous stripe shape in a plan view or partially have a lattice shape or a T-like shape to have a bridge formation in the gate trench 6. The cell structure may also partially have a polygonal shape or a wave shape, for example.

A crystal orientation of a side surface of the gate trench 6 may have any crystal plane. That is to say, the crystal orientation may have any crystal plane such as (11-20) plane, (−1120) plane, (1-100) plane, and (−1100) plane, and a type of the crystal plane is not limited.

In the embodiment 1, the surface of the semiconductor substrate 1 is (0001) plane having an OFF angle θ inclined in a [11-20] axis direction. However, even when the surface thereof is (000-1) plane having an OFF angle θ inclined in a [11-20] axis direction, a trench gate type MOSFET having a similar structure can be manufactured, and the effect of the embodiment 1 is obtained. Needless to say, also applicable is (1-100) plane or (03-38) plane.

The semiconductor device is not limited to the MOSFET. For example, when a conductivity type of the semiconductor substrate 1 is a p type or the semiconductor substrate 1 is removed to form a p-type impurity region on the lower surface of the drift layer 2 in the structure in FIG. 1, a configuration of an IGBT is constituted. In this case, the source region 4 corresponds to an emitter region in the IGBT, and the drain electrode 11 corresponds to a collector electrode in the IGBT. Even when the semiconductor device is the IGBT, an effect similar to the case of the MOSFET is obtained.

Described in the embodiment 1 is the example of using silicon carbide (SiC) as a semiconductor material constituting a semiconductor device, or the other semiconductor material may be used. Examples of the semiconductor material include Silicon (Si) or a wide bandgap material. Examples of the wide bandgap material include Ga₂O₃, gallium nitride (GaN), or diamond in addition to SiC.

Intended use under high temperature and high withstand voltage is particularly expected for the semiconductor device using the wide bandgap material. Reliability of the insulating film easily decreases under high temperature; thus, the effect of applying the embodiment 1 is significant. When the semiconductor device has high withstand voltage, voltage applied to the insulating film also increases, thus, the effect of applying the embodiment 1 is significant.

Known in a silicon carbide semiconductor device is that more electron trap occurs in a MOS interface between the gate insulating film 7 and the drift layer 2 than in Si, and reliability of the MOS interface and the gate insulating film 7 is lower than that of the silicon (Si) semiconductor device. Thus, the effect of applying the embodiment 1 capable of reducing the electrical field applied to the gate insulating film 7 is significant.

Nitrogen or phosphorus, for example, is assumed as the n-type impurity, and aluminum or boron, for example, is assumed as the p-type impurity in the embodiment 1.

### Embodiment 2

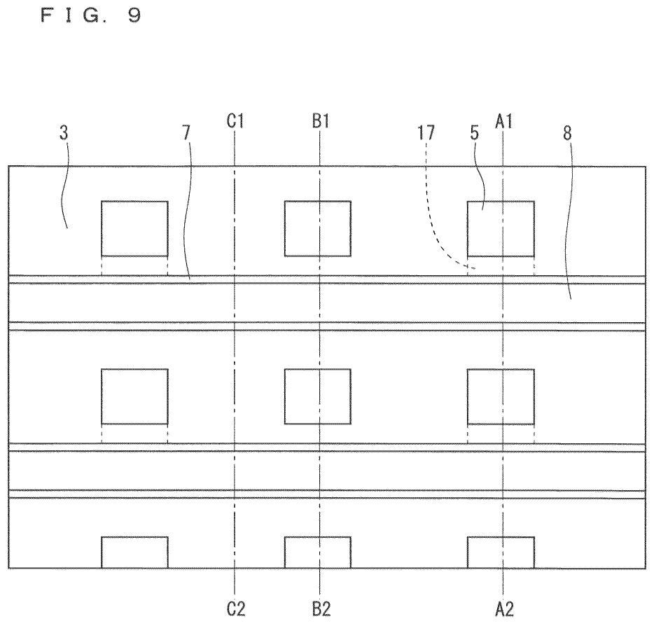

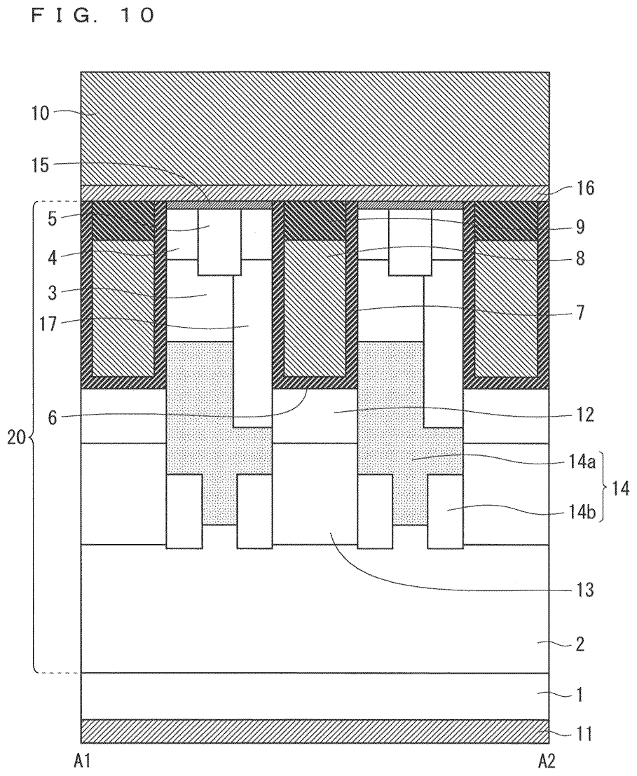

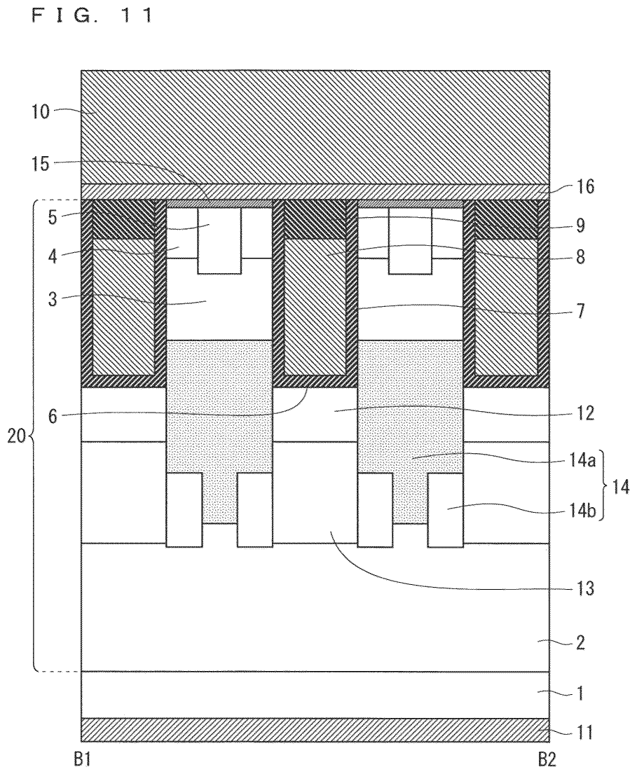

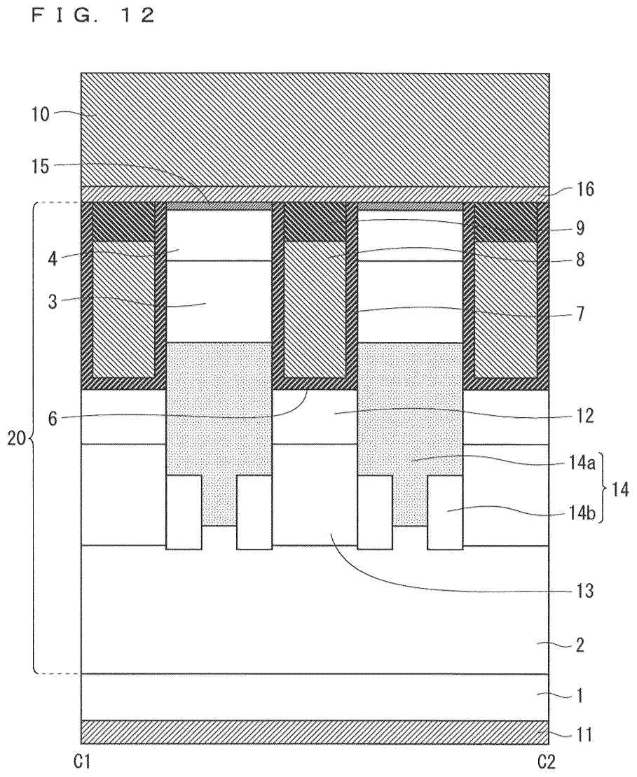

FIG. 9 is a plan view schematically illustrating a structure of a trench gate type MOSFET as a semiconductor device according to an embodiment 2. FIG. 10 is a cross-sectional view along an A1-A2 line in FIG. 9, FIG. 11 is a cross-sectional view along a B1-B2 line in FIG. 9, and FIG. 12 is a cross-sectional view along a C1-C2 line in FIG. 9.

In the embodiment 2, as illustrated in FIG. 10, a p-type sidewall well region 17 is formed in a part of a sidewall of the gate trench 6. The sidewall well region 17 has a role to electrically connect the trench bottom part protection layer 12 or the p-type pillar region 13 to the well region 3 or the well contact region 5.

In FIG. 9, illustration of some configurations is omitted to illustrate an arrangement of the sidewall well region 17 more easily. FIG. 10 to FIG. 12 illustrate a cross section of a periodic structure of a unit cell in a position including the gate trench 6 in the cross section in the active region.

As illustrated in FIG. 11, although the sidewall well region 17 is not formed in the cross section along the B1-B2 line in FIG. 9, the well contact region 5 is formed. As illustrated in FIG. 12, any of the sidewall well region 17 and the well contact region 5 are not formed in the cross section along the C1-C2 line in FIG. 9, and the well region 3 reaches the surface of the semiconductor layer 20. In this manner, the semiconductor device according to the embodiment 2 may include a part of a cross section which does not include the sidewall well region 17 but includes the well contact region 5 or a part of a cross section which does not include any of the sidewall well region 17 and the well contact region 5.

One cross section of the active region in the semiconductor device may include two or more cells each having a cross-sectional structure illustrated in FIG. 10 to FIG. 12 together. That is to say, each of the cross-sectional structures illustrated in FIG. 10 to FIG. 12 may be locally constituted. There is no limitation on a ratio of arrangement of each cross-sectional structure illustrated in FIG. 10 to FIG. 12, and design is freely performed.

A method of manufacturing the p-type sidewall well region 17 is described. The sidewall well region 17 can be formed by implanting the p-type impurity into the sidewall of the gate trench 6 by the inclined ion implantation, for example. The sidewall well region 17 may be formed with the trench bottom part protection layer 12 at the same time or separately. It is sufficient that the sidewall well region 17 is formed to have an n-type impurity concentration equal to or larger than 1×10¹⁷[cm⁻³] and equal to or smaller than 1×10²²[cm⁻³].

An effect caused by the sidewall well region 17 is described. The sidewall well region 17 electrically connects the trench bottom part protection layer 12 and the p-type pillar region 13 to the well region 3 or the well contact region 5. As a result, ensured is a current route for performing charge and discharge on a pn junction formed between the trench bottom part protection layer 12 and the p-type pillar region 13 and between the n-type pillar region 14 and the drift layer 2, and switching loss can be reduced. The sidewall well region 17 is formed only in a part of the sidewall of the gate trench 6, thus does not lead to significant reduction of the channel density, and as a result, ON resistance can be reduced.

It is also applicable that the gate trench 6 has a stripe shape in parallel to an OFF angle direction, and the gate trench 6 including a sidewall in which the sidewall well region 17 is not formed is formed. In such a case, inversion channel having uniform channel characteristics is formed; thus, such a configuration does not lead to current concentration to a specific channel surface or instability of threshold voltage, and a device having high operation stability can be achieved.

Although described in the embodiment 2 is an example of proving the sidewall well region 17 in the sidewall only on one side of the gate trench 6, the sidewall well region 17 may be provided to the sidewalls on both sides of the gate trench 6, and there is no limitation on the position where the sidewall well region 17 is formed. There is a possibility that too narrow interval between the sidewall well regions 17 leads to reduction of a channel density; thus the interval between the sidewall well regions 17 adjacent to each other is preferably equal to or larger than that between the gate trenches 6 adjacent to each other.

### Embodiment 3

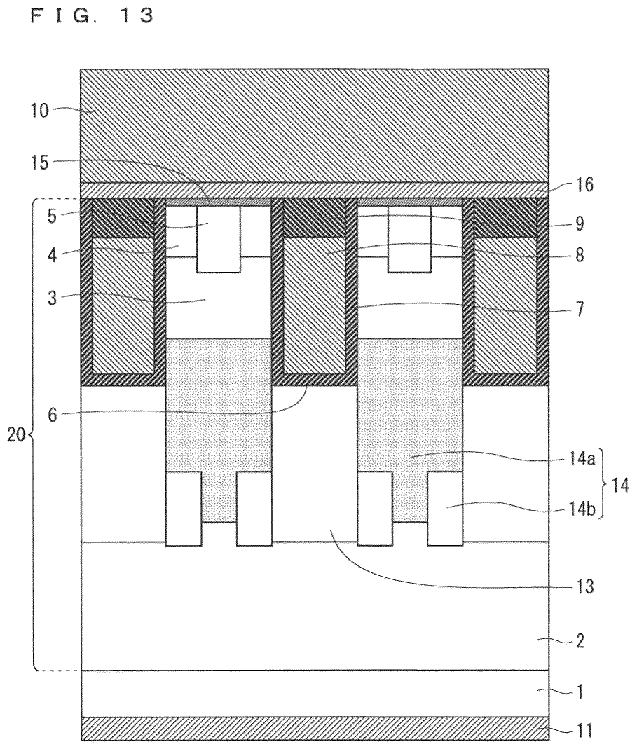

FIG. 13 is a plan view schematically illustrating a structure of a trench gate type MOSFET as a semiconductor device according to an embodiment 3. In the semiconductor device according to the embodiment 3, the trench bottom part protection layer 12 is omitted, the p-type pillar region 13 is formed to have contact with the bottom of the gate trench 6. Thus, in the embodiment 3, the p-type pillar region 13 has a role as the trench bottom part protection layer 12 reducing the electrical field applied to the bottom surface and the side surface of the gate trench 6.

According to the embodiment 3, the formation of the trench bottom part protection layer 12 can be omitted; thus, a manufacturing process can be simplified and manufacturing cost of the semiconductor device can be suppressed. The p-type pillar region 13 can reduce the electrical field applied to the bottom surface and the side surface of the gate trench 6 in place of the trench bottom part protection layer 12; thus, the effect similar to the embodiment 1 is obtained.

### Embodiment 4

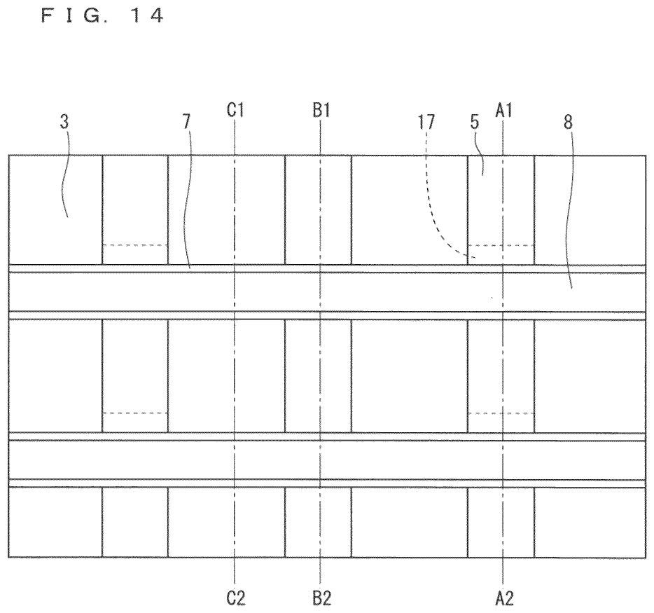

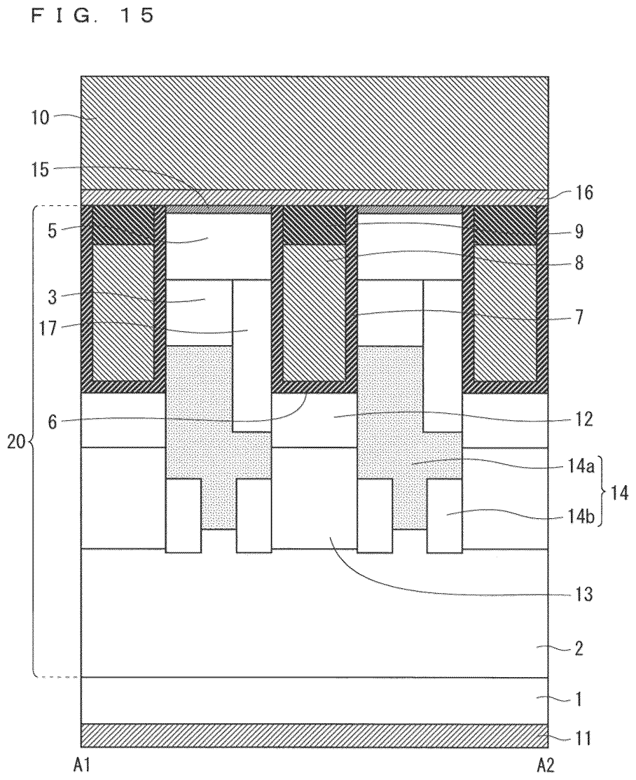

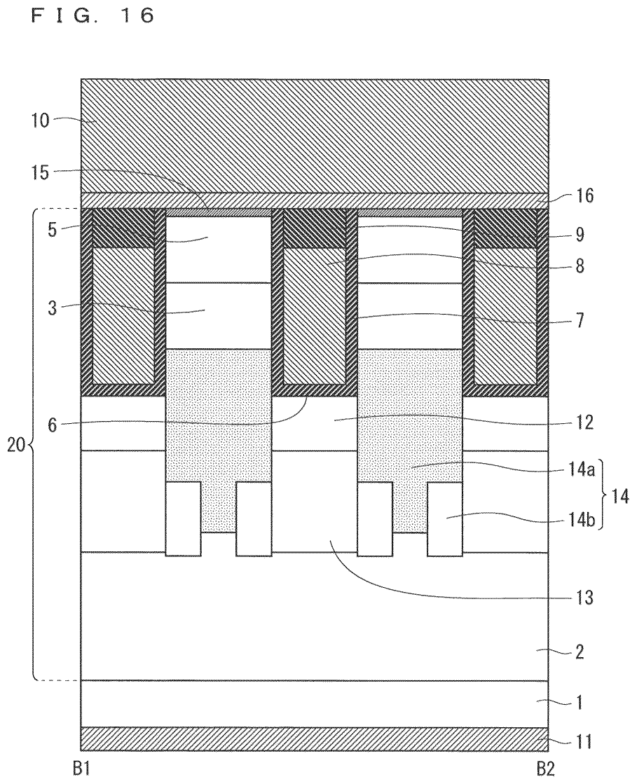

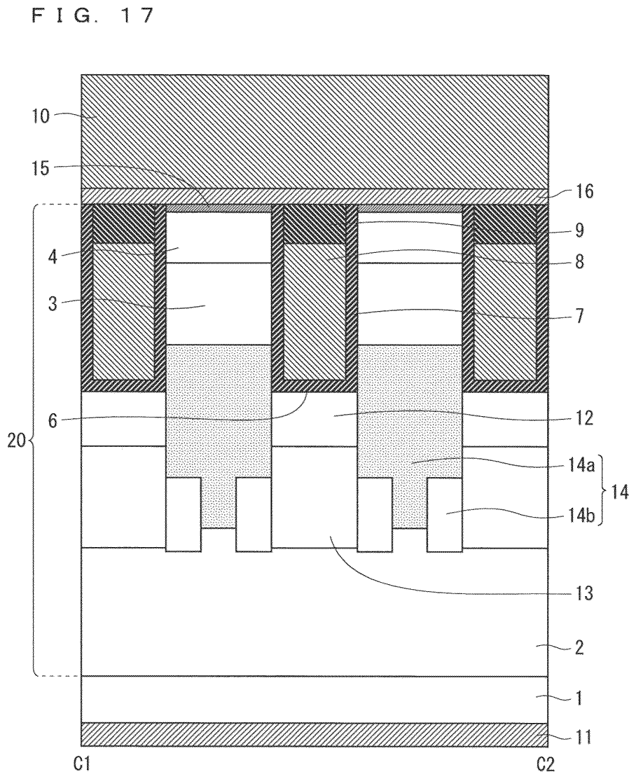

FIG. 14 is a plan view schematically illustrating a structure of a trench gate type MOSFET as a semiconductor device according to an embodiment 4. FIG. 15 is a cross-sectional view along an A1-A2 line in FIG. 14, FIG. 16 is a cross-sectional view along a B1-B2 line in FIG. 14, and FIG. 17 is a cross-sectional view along a C1-C2 line in FIG. 14.

In the embodiment 4, as illustrated in FIG. 14, the well contact region 5 is formed into a linear shape perpendicular to the gate trench 6. That is to say, the well contact region 5 extends to have contact with both the gate trenches 6 adjacent to each other across the mesa-like semiconductor layer 20 therebetween.

In the embodiment 4, the technique according to the embodiment 2 is applied, and the sidewall well region 17 is provided to a part of the sidewall of the gate trench 6. The sidewall well region 17 has a role to electrically connect the trench bottom pan protection layer 12 or the p-type pillar region 13 to the well region 3 or the well contact region 5.

As illustrated in FIG. 15, the sidewall well region 17 is formed to have contact with the well contact region 5 in the cross section along the A1-A2 line in FIG. 14. As illustrated in FIG. 16, although the sidewall well region 17 is not formed in the cross section along the B1-B2 line in FIG. 14, the well contact region 5 is formed. As illustrated in FIG. 17, any of the sidewall well region 17 and the well contact region 5 are not formed in the cross section along the C1-C2 line in FIG. 9, and the well region 3 reaches the surface of the semiconductor layer 20.

For example, in a case where the well contact region 5 has an island-like shape as a plan view in FIG. 9 described in the embodiment 2, when a deviation occurs in a photomechanical process, there is a possibility that the position of the well contact region 5 is deviated with respect to the gate trench 6, and variation occurs in channel characteristics.

In contrast, in the embodiment 4, the well contact region 5 has the linear shape perpendicular to the gate trench 6. Accordingly, even when the deviation occurs in the positioning in the photomechanical process, the deviation does not have influence on the position of the well contact region 5 with respect to the gate trench 6; thus, occurrence of variation in the channel characteristics is prevented.

The sidewall well region 17 electrically connects the trench bottom part protection layer 12 and the p-type pillar region 13 to the well contact region 5; thus, ensured is the current route for performing charge and discharge on the pn junction formed between the trench bottom part protection layer 12 and the p-type pillar region 13 and between the n-type pillar region 14 and the drift layer 2, and switching loss can be reduced.

### Embodiment 5

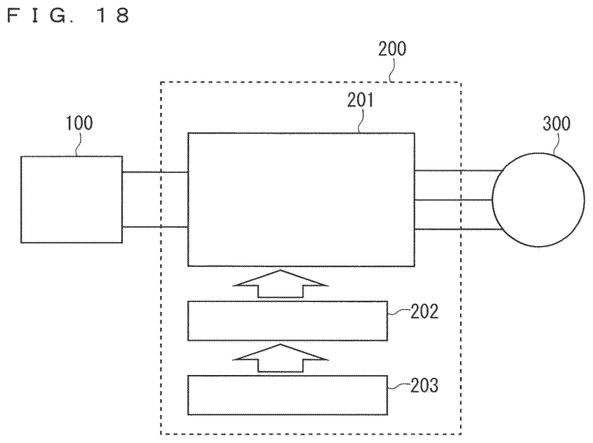

FIG. 18 is a block diagram illustrating a configuration of a power conversion system to which a power conversion apparatus according to the embodiment 5 is applied. The power conversion system illustrated in FIG. 18 is made up of a power source 100, a power conversion apparatus 200, and a load 300. The power source 100 is a direct current power source, and supplies direct current power to the power conversion apparatus 200. The power source 100 can be made up of various components, thus can be made up of a direct current system, a solar battery, or a storage battery, for example, and may also be made up of a rectification circuit connected to an alternating current system or an AC/DC converter. The power source 100 may also be made up of a DC/DC converter converting direct current power outputted from a direct current system into predetermined electrical power.

The power conversion apparatus 200 is a three-phase inverter connected between the power source 100 and the load 300, converts direct current power supplied from the power source 100 into alternating current power, and supplies the alternating current power to the load 300. As illustrated in FIG. 18, the power conversion apparatus 200 includes a main conversion circuit 201 converting direct current power into alternating current power and outputs the alternating current power, a drive circuit 202 outputting a drive signal driving each switching element of the main conversion circuit 201, and a control circuit 203 outputting a control signal controlling the drive circuit 202 to the drive circuit 202.

The load 300 is a three-phase electrical motor driven by the alternating current power supplied from the power conversion apparatus 200. The load 300 is not for a specific purpose of usage, but is an electrical motor mounted on various types of electrical apparatus, thus is used as an electrical motor for a hybrid automobile, an electrical automobile, a railroad vehicle, an elevator, or an air-conditioning machine, for example.

Details of the power conversion apparatus 200 are described hereinafter. The main conversion circuit 201 includes a switching element and a reflux diode (not shown), and when the switching element is switched, the main conversion circuit 201 converts the direct current power supplied from the power source 100 into the alternating current power, and supplies the alternating current power to the load 300. There are various specific circuit configurations of the main conversion circuit 201. The main conversion circuit 201 according to the present embodiment is a three-phase full-bridge circuit with two levels, and can be made up of six switching elements and six reflux diodes antiparallel to the switching elements, respectively. The semiconductor device according to any one of the embodiments 1 to 4 described above and the modification examples thereof is applied to each switching element of the main conversion circuit 201. The six switching elements are connected two by two in series to constitute upper and lower arms, and each pair of the upper and lower arms constitutes each phase (U phase, V phase, and W phase) of a full-bridge circuit. Output terminals of each pair of the upper and lower arms, that is to say, three output terminals of the main conversion circuit 201 are connected to the load 300.

The drive circuit 202 generates the drive signal driving the switching element of the main conversion circuit 201, and supplies the drive signal to a control electrode of the switching element of the main conversion circuit 201. Specifically, the drive circuit 202 outputs a drive signal for making the switching element enter an ON state and a drive signal for making the switching element enter an OFF state to a control electrode of each switching element in accordance with a control signal from the control circuit 203 describe hereinafter. When the switching element is kept in the ON state, the drive signal is a voltage signal (ON signal) equal to or larger than a threshold voltage of the switching element, and when the switching element is kept in the OFF state, the drive signal is a voltage signal (OFF signal) smaller than the threshold voltage of the switching element.

The control circuit 203 controls the switching element of the main conversion circuit 201 so that desired electrical power is supplied to the load 300. Specifically, the control circuit 203 calculates a time (ON time) at which each switching element of the main conversion circuit 201 should enter the ON state based on the electrical power to be supplied to the load 300. For example, the control circuit 203 can control the main conversion circuit 201 by PWM control modulating the ON time of the switching element in accordance with the voltage to be outputted. Then, the control circuit 203 outputs to a control command (control signal) to the drive circuit 202 so that the ON signal is outputted to the switching element which should enter the ON state and the OFF signal is outputted to the switching element which should enter the OFF state at each point of time. The drive circuit 202 outputs the ON signal or the OFF signal as the drive signal to the control electrode of each switching element in accordance with the control signal.

In the power conversion apparatus according to the present embodiment, the semiconductor device according to the embodiments 1 to 4 can be applied as a switching element of the main conversion circuit 201; thus, a power conversion apparatus with low loss can be achieved.

Described in present embodiment is the example of applying the semiconductor device according to the embodiments 1 to 4 to the three-phase inverter with two levels. However, the semiconductor device according to the embodiments 1 to 4 is not limited thereto, but can be applied to various power conversion apparatuses. The power conversion apparatus with two levels is described in the present embodiment; however, a power conversion apparatus with three levels or multiple levels is also applicable, and the present disclosure may be applied to a single-phase inverter when the electrical power is supplied to a single-phase load. When the electrical power is supplied to a direct current load, for example, the present disclosure can be applied to a DC/DC converter or an AC/DC converter.

The power conversion apparatus applying the semiconductor device according to the embodiments 1 to 4 can be used not only in the case where the load described above is the electrical motor but can be used as a power source apparatus of an electrical discharge machine, a laser beam machine, an induction heat cooking machine, or a wireless chagrining system, and further can also be used as a power conditioner of a solar power system or an electricity storage system, for example.

Each embodiment can be arbitrarily combined, or each embodiment can be appropriately varied or omitted.

The foregoing description is in all aspects illustrative, and is therefore understood that numerous modification examples not illustrated can be devised.

### EXPLANATION OF REFERENCE SIGNS

1 semiconductor substrate, 2 drift layer, 3 well region, 4 source region, 5 well contact region. 6 gate trench, 7 gate insulating film, 8 gate electrode, 9 interlayer insulating film, 10 source electrode, 11 drain electrode, 12 trench bottom part protection layer, 13 p-type pillar region, 14 n-type pillar region, 14a high concentration n-type pillar region, 14b low concentration n-type pillar region, 15 silicide layer, 16 barrier metal, 17 sidewall well region, 18 etching mask, 20 semiconductor layer, 100 power source, 200 power conversion apparatus, 201 main conversion circuit, 202 drive circuit. 203 control circuit, 300 load.

1. A semiconductor device, comprising:
a semiconductor layer;
a drift layer of a first conductivity type formed on the semiconductor layer;
a well region of a second conductivity type formed on a surface layer part of the semiconductor layer;
a source region of a first conductivity type formed on a surface layer part of the well region;
a source electrode electrically connected to the well region and the source region;
a plurality of gate trenches passing through the source region and the well region and having an embedded gate electrode via a gate insulating film;
first pillar regions of a second conductivity type each formed on a lower side of the plurality of gate trenches; and
a second pillar region of a first conductivity type formed between the first pillar regions adjacent to each other and having a higher impurity peak concentration than the drift layer; wherein
the second pillar region is made up of a high concentration region and a low concentration region provided to at least one lateral part of the second pillar region and having a lower impurity peak concentration than the high concentration region, and
a depth from a surface of the semiconductor layer is different between the high concentration region and the low concentration region.

2. The semiconductor device according to claim 1, further comprising
a trench bottom part protection layer of a second conductivity type formed on a bottom part of each of the gate trenches and having a higher impurity peak concentration than the first pillar regions, wherein
the first pillar regions are formed on a lower side of the trench bottom part protection layer.

3. The semiconductor device according to claim 1, wherein
the low concentration region is provided to a lateral part on both sides of the second pillar region.

4. The semiconductor device according to claim 1, wherein
a concentration of an impurity of a first conductivity type included in the first pillar regions is lower than a concentration of an impurity of a first conductivity type included in the low concentration region.

5. The semiconductor device according to claim 1, wherein
a lower end of the low concentration region is located in a position deeper from a surface of the semiconductor layer than a lower end of each of the first pillar regions.

6. The semiconductor device according to claim 1, wherein
a depth from a bottom of each of the gate trenches to a lower end of each of the first pillar regions is larger than a distance between the gate trenches adjacent to each other.

7. The semiconductor device according to claim 1, wherein
a depth from a bottom of each of the gate trenches to a lower end of each of the first pillar regions is larger than a distance between the first pillar regions adjacent to each other.

8. The semiconductor device according to claim 1, further comprising
a well contact region of a second conductivity type formed on a surface layer part of the well region to have contact with the source region and having a higher impurity peak concentration than the well region.

9. The semiconductor device according to claim 8, wherein
the well contact region is formed into a linear shape perpendicular to each of the gate trenches.

10. The semiconductor device according to claim 2, further comprising
sidewall well regions of a second conductivity type formed in a part of a sidewall of each of the gate trenches to electrically connect the trench bottom part protection layer and each of the first pillar regions to the source electrode.

11. The semiconductor device according to claim 10, wherein
an interval of the sidewall well regions adjacent to each other is equal to or larger than an interval between the gate trenches adjacent to each other.

12. The semiconductor device according to claim 10, further comprising
a well contact region of a second conductivity type formed on a surface layer part of the well region to have contact with the source region and having a higher impurity peak concentration than the well region, wherein
each of the sidewall well regions has contact with the well contact region.

13. The semiconductor device according to claim 12, wherein
the well contact region is formed into a linear shape perpendicular to each of the gate trenches.

14. A power conversion apparatus, comprising:
a main conversion circuit including the semiconductor device according to claim 1, converting electrical power which has been input, and outputting the electrical power;
a drive circuit outputting a drive signal for driving the semiconductor device to the semiconductor device; and
a control circuit outputting a control signal for controlling the drive circuit to the drive circuit.

15. A method of manufacturing a semiconductor device, comprising:
forming a semiconductor layer including a drift layer of a first conductivity type;
forming a well region of a second conductivity type on a surface layer part of the semiconductor layer;
forming a source region of a first conductivity type on a surface layer part of the well region;
forming a plurality of gate trenches passing through the source region and the well region;
forming first pillar regions of a second conductivity type on a lower side of the plurality of gate trenches;
forming a second pillar region of a first conductivity type having a higher impurity peak concentration than the drift layer between the first pillar regions adjacent to each other;
forming a gate electrode in the plurality of gate trenches via a gate insulating film; and
forming a source electrode electrically connected to the well region and the source region; wherein
the second pillar region is made up of a high concentration region and a low concentration region provided to at least one lateral part of the second pillar region and having a lower impurity peak concentration than the high concentration region,
the high concentration region and the low concentration region are formed by implanting an impurity of a first conductivity type in a side surface of each of the plurality of gate trenches by ion implantation with an angle inclined with respect to a depth direction of the semiconductor layer, and
a depth from a surface of the semiconductor layer is different between the high concentration region and the low concentration region.

16. The semiconductor device according to claim 1, wherein
a lower end of the second pillar region has a depth from the surface of the semiconductor layer equal to a lower end of each of the first pillar regions or larger than the lower end of each of the first pillar regions.

17. The semiconductor device according to claim 1, wherein
the gate trenches have an embedded interlayer insulating film covering the gate electrode.
